(19) United States
(12) Patent Application Publication
(10) Pub. No.: US 2023/0298990 A1
(43) Pub. Date: Sep. 21, 2023

(54) SEMICONDUCTOR DEVICE

(71) Applicant: ROHM CO., LTD., Kyoto-shi, Kyoto (JP)

(72) Inventor: Akihiro KOGA, Kyoto-shi, Kyoto (JP)

(21) Appl. No.: 18/023,272

(22) PCT Filed: Oct. 6, 2021
(86) PCT No.: PCT/JP2021/036925

§ 371 Date: Feb. 24, 2023

(30) Foreign Application Priority Data
Oct. 19, 2020 (JP) 2020-175198

(51) Int. Cl. H01L 23/498; H01L 23/495; H01L 23/367; H01L 23/00; H01L 25/16

(52) U.S. Cl. CPC H01L 23/49861; H01L 23/49575; H01L 23/49548; H01L 23/49513; H01L 23/367; H01L 24/48; H01L 25/16; H01L 2224/48247; H01L 2224/48139; H01L 2224/49171; H01L 2924/18165; H01L 2924/13091; H01L 2924/13055; H01L 2924/12; H01L 24/49

(57) ABSTRACT

A semiconductor device includes a lead, a semiconductor element, and a sealing resin. The lead includes an island portion having an obverse surface and a reverse surface facing opposite sides in a thickness direction. The semiconductor element is mounted on the obverse surface of the island portion. The sealing resin covers the semiconductor element and the island portion. The sealing resin has a first portion and a second portion that overlaps with the island portion as viewed in the thickness direction. The sealing resin is configured such that the infrared transmittance of the second portion is higher than that of the first portion.

### TECHNICAL FIELD

The present disclosure relates to a semiconductor device.

### BACKGROUND ART

Conventionally, various semiconductor devices have been known. One of them is called an IPM (Intelligent Power Module). This semiconductor device includes a plurality of semiconductor elements, a plurality of island portions, a heat dissipation member, and a sealing resin. The plurality of semiconductor elements are respectively mounted on the plurality of island portions. Each island portion is joined to the heat dissipation member. The sealing resin covers the plurality of semiconductor elements, the plurality of island portions, and the heat dissipation member. An example of an IPM is described in Patent Document 1, for example.

In general, each semiconductor element generates heat when the IPM is used. This heat generation can be detected by a temperature measuring element such as a thermistor. The thermistor is provided, for example, on an island portion on which a semiconductor element whose temperature is to be measured is mounted, and is arranged at a position spaced apart from the semiconductor element.

### PRIOR ART DOCUMENTS

### Patent Document

Patent Document 1: JP 2011-243839A

### SUMMARY OF INVENTION

### Problem to be Solved by the Invention

In the above configuration, it is necessary to provide a region for mounting the thermistor on the island portion. Therefore, there is concern that the size of the semiconductor device will increase. Also, the temperature is detected by the thermistor based on the fact that heat from the semiconductor element is transmitted to the thermistor via the island portion, and as a result, the resistance value of the thermistor changes. Such a conventional temperature detection method still has room for improvement in terms of accurately measuring the heat generation state of the semiconductor element.

In view of the circumstances described above, an object of the present disclosure may be to provide a semiconductor device capable of more accurate temperature measurement while avoiding an increase in size.

### Means for Solving the Problem

A semiconductor device provided by the present disclosure includes: a lead including an island portion having an obverse surface and a reverse surface that face mutually opposite sides in a thickness direction; a semiconductor element mounted on the obverse surface of the island portion; and a sealing resin covering the semiconductor element and the island portion. The sealing resin includes a first portion and a second portion that overlaps with the island portion as viewed in the thickness direction and has a higher infrared transmittance than the first portion.

### Advantages of Invention

According to the above configuration, more accurate temperature measurement is possible while avoiding an increase in the size of the semiconductor device.

Other features and advantages of the present disclosure will become more apparent from the detailed description below with reference to the accompanying drawings.

### BRIEF DESCRIPTION OF THE DRAWINGS

FIG. 1 is a perspective view showing a semiconductor device according to a first embodiment of the present disclosure.

FIG. 2 is a plan view showing the semiconductor device of FIG. 1.

FIG. 3 is a plan view showing the semiconductor device of FIG. 1.

FIG. 4 is a front view showing the semiconductor device of FIG. 1.

FIG. 5 is a side view showing the semiconductor device of FIG. 1.

FIG. 6 is a cross-sectional view of a main part taken along line VI-VI of FIG. 3.

FIG. 7 is a cross-sectional view of a main part taken along line VII-VII of FIG. 3.

FIG. 8 is an enlarged plan view of a main part showing the semiconductor device of FIG. 1.

FIG. 9 is a cross-sectional view of a main part taken along line IX-IX of FIG. 8.

FIG. 10 is a cross-sectional view of a main part taken along line X-X of FIG. 8.

FIG. 11 is an enlarged plan view of a main part showing the semiconductor device of FIG. 1.

FIG. 12 is an enlarged cross-sectional view of a main part taken along line XII-XII of FIG. 11.

FIG. 13 is a cross-sectional view of a main part showing an example of a method for manufacturing the semiconductor device of FIG. 1.

FIG. 14 is a cross-sectional view of a main part showing an example of a method for manufacturing the semiconductor device of FIG. 1.

FIG. 15 is a cross-sectional view of a main part showing a modified example of a semiconductor device according to a first embodiment of the present disclosure.

FIG. 16 is a cross-sectional view of a main part showing an example of a method for manufacturing the semiconductor device of FIG. 15.

FIG. 17 is a plan view showing a semiconductor device according to a second embodiment of the present disclosure.

FIG. 18 is a plan view showing a semiconductor device according to a third embodiment of the present disclosure.

FIG. 19 is a cross-sectional view taken along line XIX-XIX of FIG. 18.

FIG. 20 is a cross-sectional view of a main part showing an example of a method for manufacturing the semiconductor device of FIG. 18.

FIG. 21 is an enlarged plan view of a main part showing a semiconductor device according to a fourth embodiment of the present disclosure.

FIG. 22 is an enlarged cross-sectional view of a main part taken along line XXII-XXII of FIG. 21.

FIG. 23 is a cross-sectional view of a main part showing an example of a method for manufacturing the semiconductor device of FIG. 21.

### EMBODIMENTS CARRYING OUT THE INVENTION

Preferred embodiments of the present disclosure will be specifically described below with reference to the drawings.

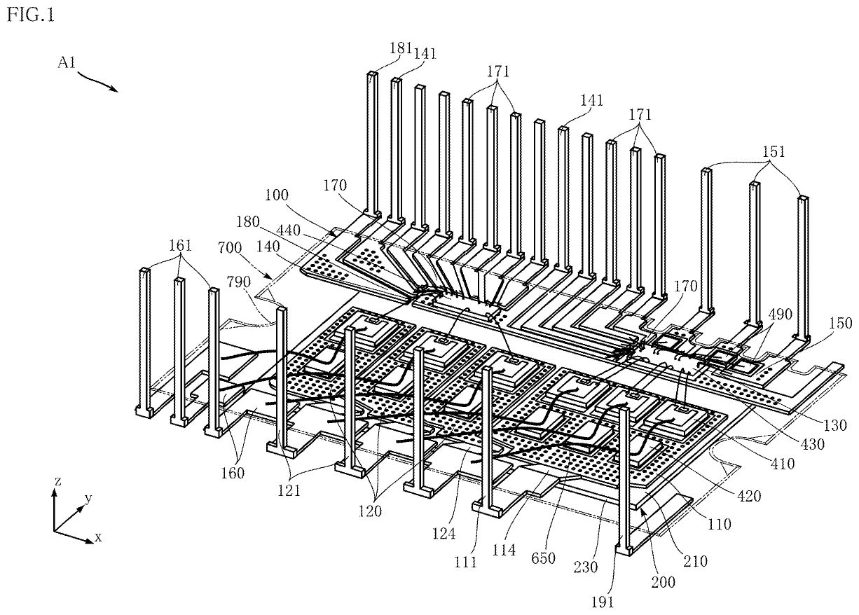

FIGS. 1 to 10 show a semiconductor device according to a first embodiment of the present disclosure. The illustrated semiconductor device A1 includes a lead 100, a heat dissipation member 200, a bonding layer 300, a plurality of semiconductor elements 410, 420, 430, and 440, a plurality of passive components 490, bonding materials 510 and 520, wires 600 and 650, and a sealing resin 700. The semiconductor device A1 is configured as an IPM used for drive control or the like of an inverter motor provided in an air conditioner, for example. An example of the size of the semiconductor device A1 is about 38 mm in the x direction, about 24 mm in the y direction, and about 3.5 mm in the z direction (thickness of the sealing resin 700).

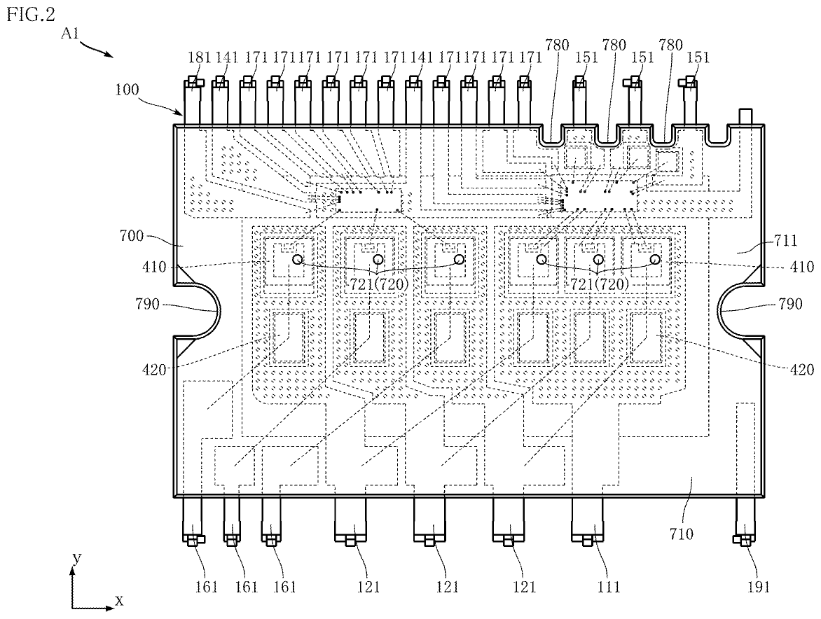

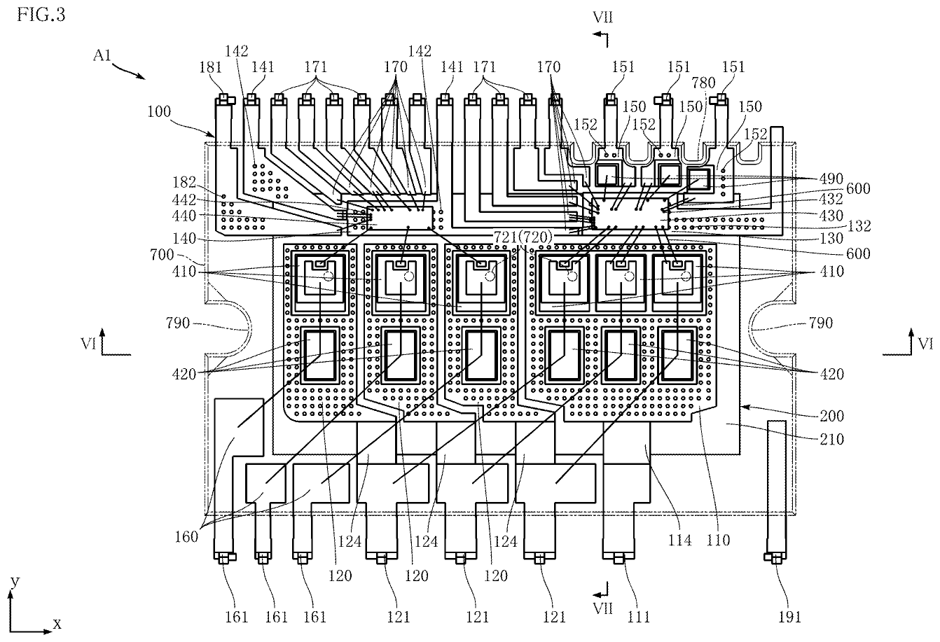

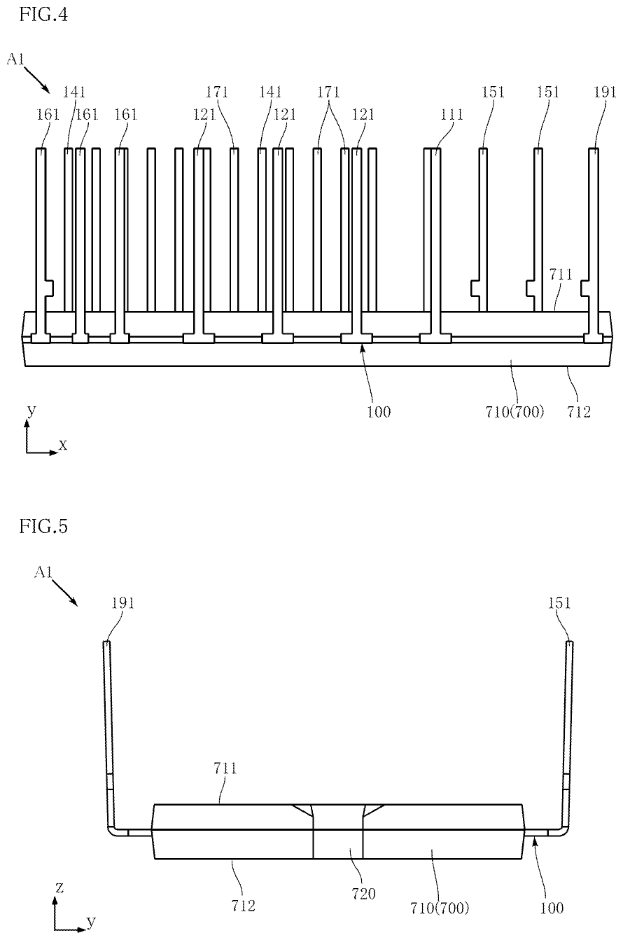

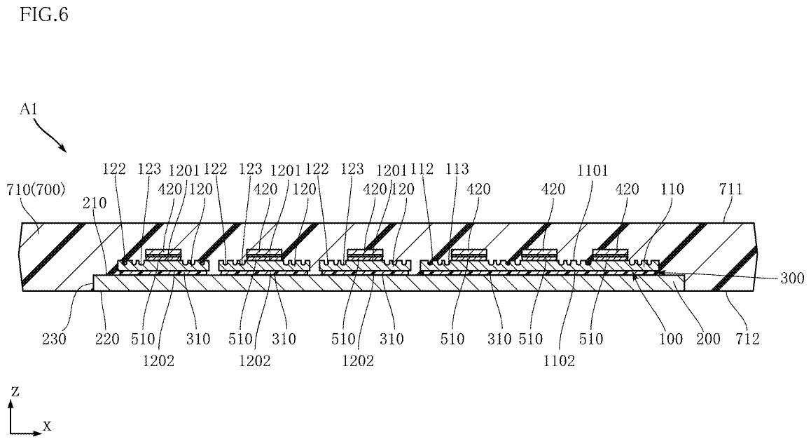

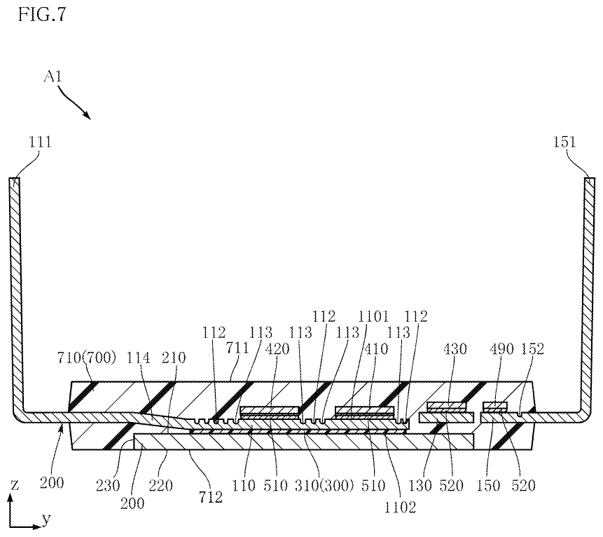

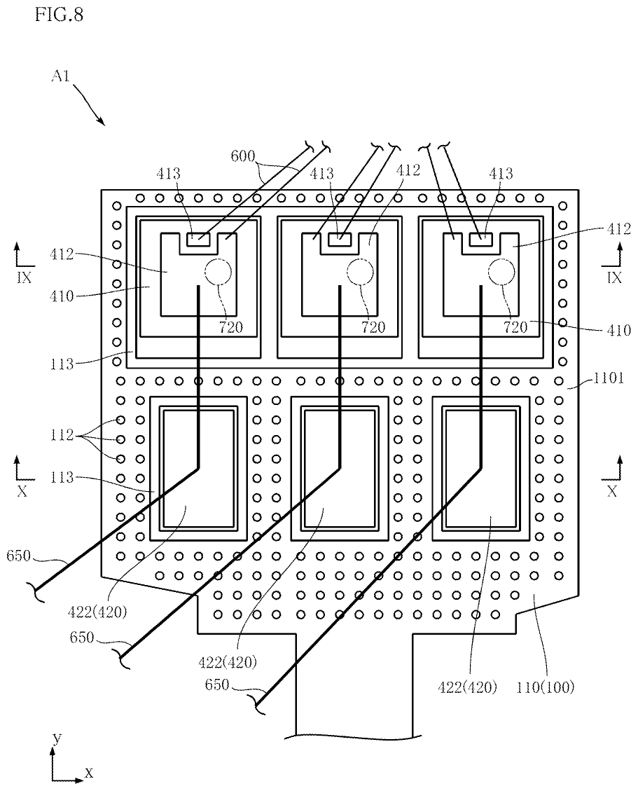

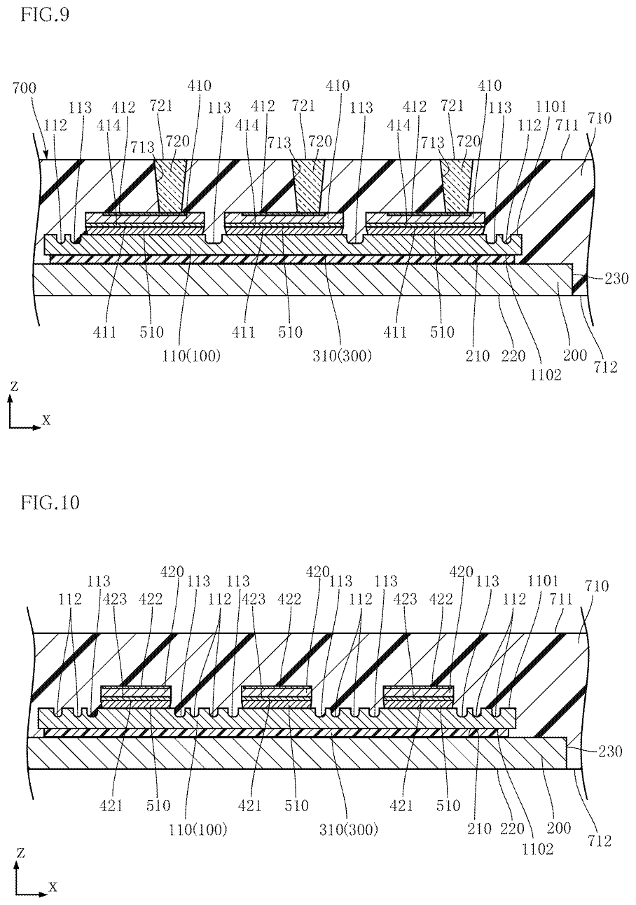

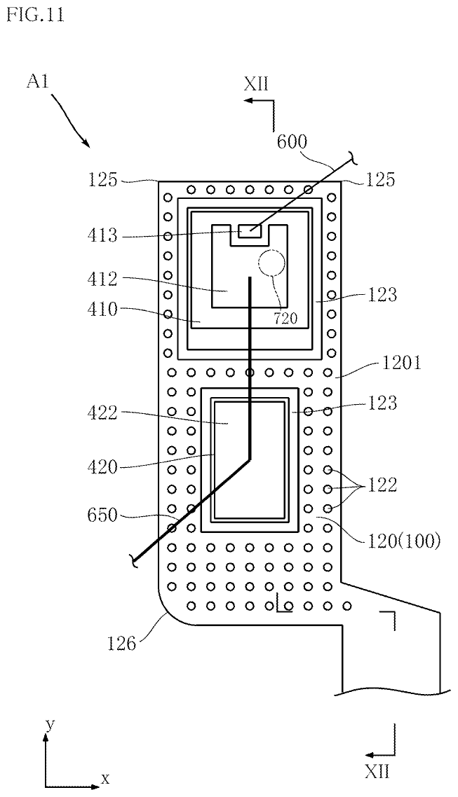

FIG. 1 is a perspective view of the semiconductor device A1, and only the main outline of the sealing resin 700 is indicated by a two-dot chain line. FIG. 2 is a plan view of the semiconductor device A1. FIG. 3 is a plan view of the semiconductor device A1, and the sealing resin 700 is indicated by a two-dot chain line. FIG. 4 is a front view of the semiconductor device A1, and FIG. 5 is a side view of the semiconductor device A1. FIG. 6 is a cross-sectional view in the zx plane taken along line VI-VI of FIG. 3, and a terminal portion, which will be described later, is omitted therefrom. FIG. 7 is a cross-sectional view in the yz plane taken along line VII-VII of FIG. 3. FIG. 8 is an enlarged plan view of a main portion showing the semiconductor device A1. FIG. 9 is a cross-sectional view of a main part taken along line IX-IX of FIG. 8. FIG. 10 is a cross-sectional view of a main part taken along line X-X of FIG. 8. FIG. 11 is an enlarged plan view of a main part showing the semiconductor device A1. FIG. 12 is an enlarged cross-sectional view of a main part taken along line XII-XII of FIG. 11. In FIG. 8, second portions 720, which will be described later, are indicated by virtual lines. The wires 600 and the wires 650 are omitted in the cross-sectional views referred to in the following description.

The lead 100 is a conductive support member that supports the semiconductor elements 410, 420, 430, and 440 and forms a conductive path to them. In this embodiment, the lead 100 has island portions 110, 120, 130, 140 and 150, pad portions 160, 170, and 180, and terminal portions 111, 121, 141, 151, 161, 171, 181, and 191. The lead 100 is made of metal, and is made of Cu in this embodiment. The thickness of the lead 100 is, for example, about 0.42 mm. The lead 100 is formed, for example, by subjecting a metal plate material to cutting such as punching and bending.

The island portions 110, 120, 130, 140, and 150 are portions on which the plurality of semiconductor elements 410, 420, 430, and 440 and the plurality of passive components 490 are mounted. In this embodiment, one island portion 110 and three island portions 120 are arranged side by side in the x direction. Likewise, the island portion 130 and the island portion 140 are arranged side by side in the x direction. A group consisting of the island portion 110 and the three island portions 120 and a group consisting of the island portion 130 and the island portion 140 are arranged side by side in the y direction. The three island portions 150 are arranged at positions adjacent to the island portion 130 in the y direction.

The island portion 110 has an obverse surface 1101 and a reverse surface 1102 facing mutually opposite sides in the z direction. Each island portion 120 has an obverse surface 1201 and a reverse surface 1202 facing mutually opposite sides in the z direction. The island portion 130 has an obverse surface 1301 and a reverse surface 1302 facing mutually opposite sides in the z direction. The island portion 140 has an obverse surface 1401 and a reverse surface 1402 facing mutually opposite sides in the z direction.

As shown in FIG. 3, the island portion 110 has a substantially rectangular shape in a plan view, and the semiconductor elements 410 and 420 are mounted on the obverse surface 1101 thereof. In this embodiment, three semiconductor elements 410 and three semiconductor elements 420 are mounted on the island portion 110. The three semiconductor elements 410 are arranged side by side in the x direction, and similarly, the three semiconductor elements 420 are arranged side by side in the x direction. Each semiconductor element 410 is spaced apart in the y direction with respect to one corresponding semiconductor element 420, and the semiconductor element 410 and the semiconductor element 420 have a common (virtual) central axis extending parallel to the y direction. In the example shown in the drawings, three parallel central axes are assumed for the three semiconductor elements 410 (and, consequently, the three semiconductor elements 420) as such central axes. Another way of describing this situation may be that three element pairs (each pair consisting of one semiconductor element 410 and one corresponding semiconductor element 420) are parallel to each other along the y direction.

A plurality of recesses 112 and a plurality of trenches 113 are formed in the island portion 110. The plurality of recesses 112 are formed on the obverse surface 1101 of the island portion 110. More accurately, each recess 112 is recessed from the obverse surface 1101 and has an opening that is flush with the obverse surface (this situation is also described as “each recess 112 being open to the obverse surface 1101” in some cases). In the present embodiment, the recesses 112 each have a circular shape in a plan view (a circular shape in a cross section orthogonal to the z direction), but the shape of the recesses is not limited to this. The plurality of recesses 112 are formed in regions of the island portion 110 other than the trenches 113 and regions surrounded by trenches 113. In this embodiment, the plurality of recesses 112 are arranged in the form of a matrix along the x direction and the y direction.

As shown in FIG. 8, each trench 113 is formed so as to surround three semiconductor elements 410 or one semiconductor element 420, and is open to the obverse surface 1101 of the island portion 110. In FIG. 8, the upper trench 113 (first trench 113) has a rectangular outer frame that is relatively long in the x direction, and two inner portions that each extend in the y direction inside the outer frame. Both ends of each inner portion are in communication with the outer frame. With such a mode, three regions (three separate regions separated from each other) that are surrounded by the first trench 113 are formed on the obverse surface 1101. The three semiconductor elements 410 are respectively arranged in these separate regions. On the other hand, the three lower trenches 113 (second trenches 113) in FIG. 8 each have a rectangular shape that is relatively long in the y direction. In each of the regions surrounded by the second trenches 113, one corresponding semiconductor element 420 is arranged. In the illustrated example, each second trench 113 is a continuous ring (closed ring) with no ends, but the present disclosure is not limited thereto. For example, a plurality of portions (for example, individual grooves) may be arranged discretely from each other so as to form a ring as a whole. Also, a configuration similar to this may also be applied to the first trench 113. Unlike the illustrated example, the island portion 110 may have a configuration in which the recesses 112 and the trenches 113 are not formed.

In FIG. 3, the three island portions 120 are arranged adjacent to and spaced apart from each other in the x direction. Starting from the left in the x direction, the three island portions 120 are respectively called a first island 120, a second island 120, and a third island 120. FIG. 11 is an enlarged plan view of a main part showing the first island portion 120 and its accompanying parts. Note that the second and third island portions 120 have the same configuration as the first island portion 120, except for some differences in shape. As shown in FIG. 11, the (first) island portion 120 has a substantially rectangular shape elongated in the y direction, and the semiconductor elements 410 and 420 are mounted thereon. In this embodiment, one semiconductor element 410 and one semiconductor element 420 are mounted on the island portion 120, and these two semiconductor elements are arranged side by side along the y direction.

As shown in FIG. 11, a plurality of recesses 122 and a plurality of trenches 123 are formed on the island portion 120. Each recess 122 is open to the obverse surface 1201 of the island portion 120. In this embodiment, each recess 122 has a circular shape in a plan view, but the present disclosure is not limited to this. The plurality of recesses 122 are formed in regions of the island portion 120 other than trenches 123 and the regions surrounded by the trenches 123. In this embodiment, the plurality of recesses 122 are arranged in the form of a matrix along the x direction and the y direction.

Each trench 123 is formed so as to surround the semiconductor element 410 or the semiconductor element 420 and is open to the obverse surface 1201 of the island portion 120. In FIG. 11, the upper trench 123 is rectangular, and the semiconductor element 410 is arranged in the region surrounded by the trench 123. Similarly, the lower trench 123 is also rectangular, and the semiconductor element 420 is arranged in the region surrounded by this trench 123. Note that, as described above with regard to the island portion 110, each trench 123 may have a configuration in which a plurality of portions are discretely arranged so as to form a ring shape as a whole, instead of having a continuous ring shape. Also, the island portion 120 may have a configuration in which the recesses 122 and the trenches 123 are not formed.

Two corner portions 125 and an arc portion 126 are formed on the island portion 120 shown in FIG. 11. The two corner portions 125 are provided at the upper end of the island portion 120 (the end separated from the later-described terminal portion 121), and the arc portion 126 is provided at the lower end of the island portion 120 (the end close to the terminal portion 121). Also, each corner portion 125 is provided on the side opposite to the semiconductor element 420 with the semiconductor element 410 as a reference. In other words, each corner portion 125 is provided at a position farther from the terminal portion 121 than the semiconductor elements 410 and 420 are. The arc portion 126 is provided on the side opposite to the semiconductor element 410 with the semiconductor element 420 as a reference. In other words, the arc portion 126 is provided at a position closer to the terminal portion 121 than the semiconductor elements 410 and 420 are. Each corner portion 125 is formed by connecting two sides adjacent to each other in the island portion 120, and in this embodiment, the two sides form an angle of 90°. The arc portion 126 is formed to smoothly connect two adjacent sides, and is, for example, an arc with a constant radius of curvature, but the present disclosure is not limited to this. For example, the radius of curvature of the arc portion 126 need not be constant over the entire arc, and the radius of curvature may partially differ.

As shown in FIGS. 1 to 3 and 7, the island portion 130 is arranged adjacent to the island portion 110 in the y direction, and has a substantially elongated rectangular shape with the x direction as the longitudinal direction. The semiconductor element 430 is mounted on the island portion 130. The semiconductor element 430 has an elongated rectangular shape whose longitudinal direction is the x direction, and the longitudinal direction of the semiconductor element 430 matches that of the island portion 130.

A plurality of recesses 132 are formed in the island portion 130. The plurality of recesses 132 are open to the surface of the island portion 130 on which the semiconductor element 430 is mounted. In this embodiment, the recesses 132 have circular cross sections, but there is no limitation to this. The plurality of recesses 132 are mainly formed in regions of the island portion 130 located away from the semiconductor element 430. Also, the recesses 132 may be formed at positions overlapping with the semiconductor element 430 as long as the semiconductor element 430 does not peel off, or the like. In this embodiment, the plurality of recesses 132 are arranged in the form of a matrix along the x direction and the y direction. The island portion 130 may also have a configuration in which the recesses 132 are not formed.

The island portion 140 is arranged adjacent to the three island portions 120 (especially the second island portion 120) in the y direction, and has a substantially elongated rectangular shape with the x direction as the longitudinal direction. A semiconductor element 440 is mounted on the island portion 140. The semiconductor element 440 has an elongated rectangular shape with the x direction as the longitudinal direction, and the longitudinal direction coincides with that of the island portion 130.

A plurality of recesses 142 are formed in the island portion 140. The plurality of recesses 142 are open to the surface of the island portion 140 on which the semiconductor element 440 is mounted. In this embodiment, the recesses 142 have circular cross sections, but there is no limitation to this. The plurality of recesses 142 are mainly formed in regions of the island portion 140 located away from the semiconductor element 440. The recesses 142 may be formed at positions overlapping with the semiconductor element 440 as long as the semiconductor element 440 does not peel off, or the like. In this embodiment, the plurality of recesses 142 are arranged in the form of a matrix along the x direction and the y direction. A plurality of recesses 142 are also formed in a substantially triangular portion connected to the island portion 140. The island portion 140 may also have a configuration in which the recesses 142 are not formed.

The three island portions 150 are arranged at positions adjacent to the island portion 130 in the y direction. The three island portions 150 are arranged side by side along the x direction. Each island portion 150 is a portion that is smaller than the island portions 110, 120, 130, and 140. Each island portion 150 has a passive component 490 mounted thereon. A plurality of recesses 152 are formed in each island portion 150. The recesses 152 are open to the surface of the island portion 150 on which the passive component 490 is mounted, and are formed at positions located away from the passive component 490. In this embodiment, the plurality of recesses 152 are arranged in the form of a matrix along the x direction and the y direction. Also, an arc-shaped notch corresponding to a groove 780 of the later-described sealing resin 700 is formed in each island portion 150. The island portions 150 may also have a configuration in which the recesses 152 are not formed.

The pad portions 160, 170, and 180 are portions that are electrically connected to the semiconductor elements 410, 420, 430, and 440 via the wires 600 and 650.

As shown in FIG. 3, the plurality of pad portions 160 are provided diagonally spaced apart from the island portions 110 and 120. Each pad portion 160 has a rectangular shape and is bonded with at least one corresponding wire 650 (see FIG. 8). In the illustrated example, six pad portions 160 are provided, but the present disclosure is not limited to this.

A plurality of pad portions 170 are arranged at locations adjacent to the island portions 130 and 140. Each pad portion 170 has a substantially rectangular shape. More specifically, each pad portion 170 is a portion near the leading end of a narrow belt-like portion. At least one corresponding wire 600 is bonded to each pad portion 170.

The pad portions 180 are arranged toward one side of the semiconductor device A1 in the x direction (toward the left side in FIG. 3). At least one corresponding wire 600 is bonded to each pad portion 180. In the example shown in the drawings, each pad portion 180 has a substantially triangular shape and a plurality of recesses 182 are formed therein. The recesses 182 are open to the surface of the pad portion 180 to which the wire 600 is bonded, and are formed at positions located away from the wire 600. In this embodiment, the plurality of recesses 182 are arranged in the form of a matrix along the x direction and the y direction.

The recesses 112, 122, 132, 142, 152, and 182 and the trenches 113, 123 described above can be formed by etching in the process of forming the lead 100, for example. Alternatively, they can be formed by providing a plurality of protrusions in a die used for cutting or bending to form the lead 100.

As can be seen from FIGS. 1, 3, and 7, the lead 100 has bent portions 114 and 124. The bent portion 114 is connected to the island portion 110 and is bent such that the side spaced apart from the island portion 110 is located upward in the z direction. The bent portion 124 is connected to the island portion 120 and is bent such that the side spaced apart from the island portion 120 is located upward in the z direction.

In this embodiment, the z direction positions of the portions of the bent portions 114 and 124 located on the upper side in the z direction and the island portions 130, 140, and 150 and the pad portions 160, 170, and 180 are substantially the same. In other words, the island portions 110 and 120 are arranged at positions slightly shifted downward in the z direction with respect to the island portions 130, 140, and 150 and the pad portions 160, 170, and 180, respectively.

The terminal portions 111, 121, 141, 151, 161, 171, 181, and 191 protrude from the sealing resin 700. These terminal portions 111, 121, 141, 151, 161, 171, 181, and 191 have bent portions bent at angles close to 90°, and one end of each faces upward in the z direction. The terminal portions 111, 121, 141, 151, 161, 171, 181, and 191 are used to mount the semiconductor device A1 on, for example, a circuit board (not shown).

The terminal portion 111 is connected to the bent portion 114 and is electrically connected to the island portion 110. The three terminal portions 121 are connected to the bent portion 124 and are electrically connected to the island portions 120. The two terminal portions 141 are connected to the island portion 140. The three terminal portions 151 are individually connected to the three island portions 150. The three terminal portions 161 are individually connected to the three pad portions 160. The plurality of terminal portions 171 are individually connected to the plurality of pad portions 170. The terminal portion 181 is connected to the pad portion 180.

In this embodiment, the intervals between the terminal portions 111, 121, 141, 151, 161, 171, 181, and 191 are not all equal. For example, regarding the intervals between the terminal portions 141, 151, 171, and 181, which are arranged side by side on the same side in the y direction, the two terminal portions 141, the plurality of terminal portions 171, and the terminal portion 181 are arranged side by side in the x direction at substantially equal intervals. On the other hand, the intervals between the three terminal portions 151 and the terminal portion 171 adjacent to these terminal portions 151 are clearly large. The grooves 780 of the later-described sealing resin 700 and the arc-shaped notches provided in the island portion 150 as described above are located between the three terminal portions 151 and the terminal portion 171 with a large interval therebetween.

The terminal portion 191 is provided spaced apart from the end portion in the x direction. In this embodiment, the terminal portion 191 is not electrically connected to the island portions 110, 120, 130, and 140, the semiconductor elements 410, 420, 430, and 440, and the like.

Also, regarding the intervals between the terminal portions 111, 121, and 161 arranged side by side on the same side in the y direction, the three terminal portions 161 are arranged side by side at relatively narrow intervals. On the other hand, the intervals between the terminal portion 111, the three terminal portions 121, and the terminal portion 161 adjacent thereto are clearly large. Also, the terminal portion 191 is arranged with an even larger interval from the terminal portion 111.

The intervals of the terminal portions 111, 121, 141, 151, 161, 171, 181, and 191 have the above relationship because of the functions of these terminal portions. For example, if the semiconductor device A1 of this embodiment is configured as an IPM, the electrical current controlled by the semiconductor device A1 is, for example, a three-phase AC current having a U-phase, a V-phase, and a W-phase. Also, the three terminal portions 121 are respectively assigned as U-phase, V-phase, and W-phase terminal portions. A relatively high voltage is applied to the three terminals 151. For this reason, terminal portions to which a relatively large electrical current flows or to which a relatively high voltage is applied have a relatively larger interval from adjacent terminals.

The heat dissipation member 200 is provided mainly to transfer heat from the semiconductor elements 410 and 420 to the outside of the semiconductor device A1. In this embodiment, the heat dissipation member 200 is made of ceramic and has a rectangular plate shape. Note that, as the heat dissipation member 200, a configuration made of ceramic is preferable from the viewpoint of strength, the heat transfer coefficient, and insulation, but various materials can be adopted.

The heat dissipation member 200 has a bonding surface 210, an exposed surface 220, and side surfaces 230. The bonding surface 210 and the exposed surface 220 face opposite sides in the thickness direction of the heat dissipation member 200 and are parallel to each other. The bonding surface 210 is bonded to the island portion 110 and the three island portions 120 via the bonding layer 300. Note that in the present embodiment, the heat dissipation member 200 overlaps with at least part of the island portions 130 and 140 in addition to the island portions 110 and 120 as viewed in the z direction. However, the heat dissipation member 200 is not bonded to the island portions 130 and 140.

The bonding layer 300 bonds the heat dissipation member 200 to the reverse surface 1102 of the island portion 110 and the reverse surfaces 1202 of the island portions 120. As the bonding layer 300, a bonding layer that appropriately bonds the heat dissipation member 200 made of, for example, ceramic and the island portions 110 and 120 made of, for example, Cu, and that has relatively good thermal conductivity is preferable, and for example, a resin adhesive with excellent thermal conductivity is used.

The semiconductor elements 410, 420, 430, and 440 are functional elements for causing the semiconductor device A1 to function as an IPM. In this embodiment, the semiconductor elements 410 and 420 are so-called power semiconductor elements. The power semiconductor element referred to in the present disclosure is, for example, a power semiconductor element to and from which a three-phase alternating current to be controlled is input and output in an IPM, and typical examples thereof include an IGBT (Insulated-Gate Bipolar Transistor), a MOSFET (Metal-Oxide-Semiconductor Field-Effect Transistor), and an FRD (Fast Recovery Diode). Also, among these power semiconductor elements, those using SiC as a base material may be employed. In this embodiment, the semiconductor element 410 is, for example, an IGBT, and the semiconductor element 420 is, for example, an FRD.

As shown in FIGS. 8 to 12, the semiconductor element 410 has a bottom surface 411, a first electrode 414, a second electrode 412 and a third electrode 413. In this embodiment, the third electrode 413 is the gate electrode (control electrode), the second electrode 412 is the emitter electrode, and the first electrode 414 is the collector electrode. The second electrode 412 and the third electrode 413 are formed on the surface of the semiconductor element 410 facing upward in the z direction, and are made of Au, for example. A wire 650 is bonded to the second electrode 412. A wire 600 is bonded to the third electrode 413. The first electrode 414 is formed so as to occupy the entire lower surface in the z direction (the bottom surface 411) of the semiconductor element 410, and is made of, for example, Au or Ag. The bottom surface 411 is a surface that is bonded to the island portions 110 and 120 via the bonding material 510, and is composed of the first electrode 414 in this embodiment.

The semiconductor element 420 has a bottom surface 421, an upper surface electrode 422, and a bottom surface electrode 423. The upper surface electrode 422 is formed on the surface of the semiconductor element 420 facing upward in the z direction, and is made of Au, for example. A wire 650 is bonded to the upper surface electrode 422. The bottom surface electrode 423 is formed so as to occupy the entire lower surface in the z direction of the semiconductor element 420, and is made of Au or Ag, for example. The bottom surface 421 is a surface that is bonded to the island portions 110 and 120 via the bonding material 510, and is constituted by the bottom surface electrode 423 in this embodiment.

The bonding material 510 bonds the semiconductor elements 410 and 420 to the island portions 110 and 120. In this embodiment, solder is used as the bonding material 510. The solder, which is the bonding material 510, bonds the semiconductor elements 410 and 420 and the island portions 110 and 120 to each other by going through a molten state and then hardening. In this embodiment, the first electrode 414 of the semiconductor element 410 and the bottom electrode 423 of the semiconductor element 420 are made of Au or Ag, and the island portions 110 and 120 are made of Cu, whereby the wettability with respect to the molten solder, that is, the bonding material 510 on the bottom surfaces 411 and 421 of the semiconductor elements 410 and 420, is superior to that of the island portions 110 and 120. Note that the bonding material 510 is not limited to solder, and may be Ag paste, calcined silver, or the like.

In this embodiment, the semiconductor elements 430 and 440 are so-called control semiconductor elements. The control semiconductor element referred to in the present disclosure has a function of controlling the operation of the power semiconductor element described above, and is, for example, a driver IC or the like. In this embodiment, both of the semiconductor elements 430 and 440 are driver ICs. Also, the semiconductor element 430 is a high-voltage driver IC that handles relatively high-voltage current, and the semiconductor element 440 is a low-voltage driver IC that handles relatively low-voltage current.

As shown in FIG. 3, the semiconductor elements 430 and 440 have a plurality of upper surface electrodes 432 and 442. Wires 600 are bonded to the upper surface electrodes 432 and 442. As shown in FIG. 7, the semiconductor element 430 is bonded to the island portion 130 via the bonding material 520. The bonding material 520 is Ag paste, for example. The semiconductor element 440 is similarly bonded to the island portion 140 via the bonding material 520 made of Ag paste, for example.

The passive component 490 is a single-function electronic component such as a resistor, a capacitor, or a coil, and acts on the electrical current to the semiconductor element 430 in this embodiment. The passive component 490 is bonded to the island portion 150 via the bonding material 520. A wire 600 is bonded to the upper surface of the passive component 490 in the z direction.

The wires 600 and 650, together with the lead 100 described above, form conductive paths for the semiconductor elements 410, 420, 430, and 440 and the passive component 490 to perform their predetermined functions. In this embodiment, the wires 600 are used to form conduction paths through which a relatively small electrical current flows, and the wires 650 are used to form conduction paths through which a relatively large electrical current flows. The wires 600 are made of Au, for example, and have a diameter of, for example, about 38 μm. The wires 650 are made of Al, for example, and have a diameter of about 400 μm, for example.

The sealing resin 700 partially or wholly covers the lead 100, the semiconductor elements 410, 420, 430, and 440, the passive component 490, and the wires 600 and 650. The sealing resin 700 has a first portion 710 and a plurality of second portions 720.

The first portion 710 and the second portions 720 have mutually different infrared transmittances. The infrared transmittance of the second portions 720 is higher than the infrared transmittance of the first portion 710. There is no limitation at all on the materials of the first portion 710 and the second portions 720. The material of the first portion 710 is, for example, a black epoxy resin into which a filler is mixed. Examples of the material of the second portions 720 include an epoxy resin that transmits almost all infrared rays with a wavelength of about 770 to 1000 nm but blocks almost all visible light with a wavelength of 770 nm or less. Note that the material of the second portions 720 may be a general transparent resin that transmits not only infrared rays but also visible light.

The first portion 710 constitutes most of the sealing resin 700. The first portion 710 has a resin obverse surface 711 and a resin reverse surface 712. The resin obverse surface 711 and the resin reverse surface 712 are surfaces facing mutually opposite sides in the z direction.

Also, as shown in FIG. 2, four grooves 780 and two grooves 790 are formed in the first portion 710. The four grooves 780 are recessed in the y direction and extend in the z direction. The four grooves 780 are provided at positions between the three terminals 151 and 171 and adjacent to the terminal 151. Corresponding to these grooves 780, as shown in FIG. 3, arc-shaped notches are formed in the island portion 150. Also, as described above, the intervals between the three terminal portions 151 are relatively large.

The two grooves 790 are provided at both ends in the x direction, are recessed in the x direction, and extend in the z direction. These grooves 790 are used, for example, when transporting or attaching the semiconductor device A1, or the like.

As can be seen from FIGS. 6, 7, 9, 10 and 12, the sealing resin 700 enters the recesses 112, 122, 132, 142, 152, and 182 and the trenches 113 and 123 of the lead 100. Also, in this embodiment, the sealing resin 700 covers the entire side surface 230 of the heat dissipation member 200, and the surface facing downward in the z direction is flush with the exposed surface of the heat dissipation member 200.

The second portions 720 overlap with the island portion 110 or the island portion 120 as viewed in the z direction, and are arranged on the side faced by the obverse surface 1101 and the obverse surface 1201 with respect to the island portion 110 or the island portions 120. The second portion 720 of the present embodiment overlaps with the semiconductor element 410 as viewed in the z direction and is included in the semiconductor element 410. Furthermore, in the illustrated example, the second portion 720 overlaps with the second electrode 412 of the semiconductor element 410 as viewed in the z direction. Also, the second portion 720 of this embodiment is spaced apart from the wire 650 as viewed in the z direction.

As shown in FIGS. 9 and 12, recesses 713 are formed in the first portion 710. The recesses 713 are portions recessed in the z direction from the resin obverse surface 711. The recesses 713 may be in a form penetrating part of the resin obverse surface 711, or may be in the form of non-penetrating bottomed recesses. In the illustrated example, the recesses 713 penetrate part of the resin obverse surface 711 in the z direction and reach the second electrode 412 of the semiconductor element 410.

The second portions 720 are accommodated in the recesses 713. The second portions 720 have exposed surfaces 721. The exposed surfaces 721 are exposed from the resin obverse surface 711 of the first portion 710 in the z direction. In the illustrated example, the second portions 720 are in contact with the semiconductor elements 410, and for example, are in contact with the second electrodes 412. The shape of the second portions 720 is not limited at all. In the illustrated example, the second portions 720 have tapered cylindrical shapes whose diameters decrease from the resin obverse surface 711 toward the semiconductor element 410 in the z direction.

In this embodiment, six second portions 720 are provided in correspondence with the six semiconductor elements 410. Alternatively, the number of second portions 720 may differ from the number of semiconductor elements 410. For example, a configuration may be used in which the second portion 720 overlapping one of the three semiconductor elements 410 mounted on the island portion 110 is provided, and no second portion 720 overlapping the semiconductor element 410 is provided on the other two.

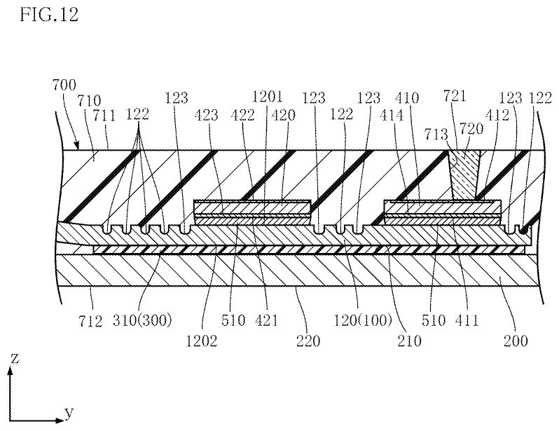

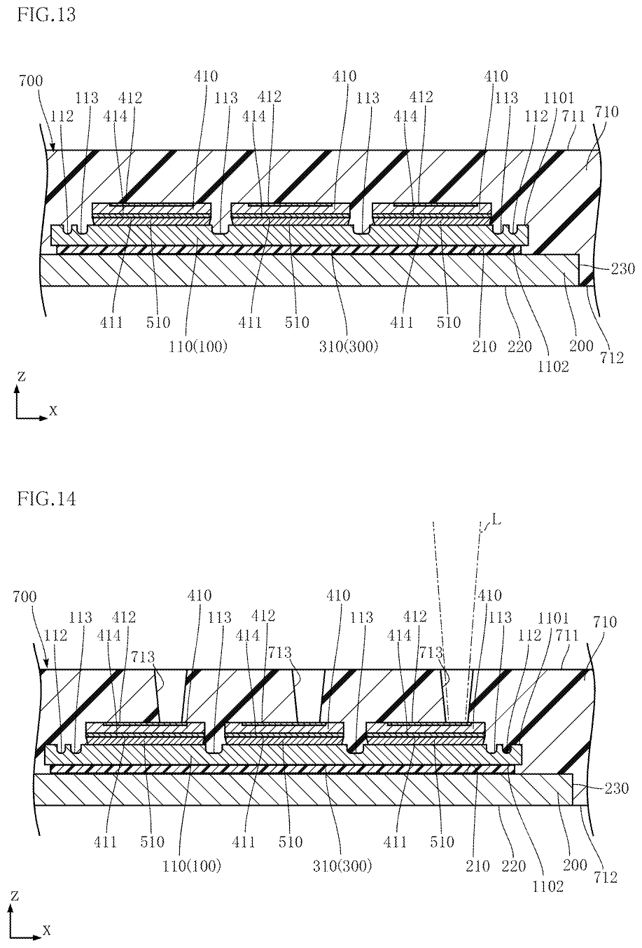

FIGS. 13 and 14 are enlarged cross-sectional views of a main portion showing an example of the method of manufacturing the semiconductor device A1. In FIG. 13, after the mounting of the semiconductor element 410, the semiconductor element 420, the semiconductor element 430, and the semiconductor element 440 on the lead 100 and the bonding of the wires 600 and 650 are completed, the first portion 710 shown in FIG. 10 is formed with use of, for example, a mold. A plurality of recesses 713 are not yet formed in the first portion 710 at this stage.

Next, as shown in FIG. 14, a plurality of recesses 713 are formed in the first portion 710. The method for forming the recesses 713 is not limited at all, as long as it is possible to remove appropriate locations of the first portion 710. Examples of such a method include a method using laser light and a method using etching. In the illustrated example, part of the first portion 710 is removed by emitting a laser beam L to the resin obverse surface 711 of the first portion 710. A plurality of recesses 713 are formed in the first portion 710 through this processing using laser beam. In the illustrated example, the recesses 713 reach the second electrode 412 of semiconductor element 410.

Then, the recesses 713 are filled with, for example, a liquid resin material, and the resin material is cured. Thereby, the second portion 720 shown in FIGS. 9 and 12 is obtained.

Next, operations of the semiconductor device A1 will be described.

According to this embodiment, the sealing resin 7 has a first portion 710 and second portions 720, as shown in FIGS. 2, 3, 8, 9, 11, and 12. The second portions 720 are made of a material having higher infrared transmittance than the first portion 710. Also, the second portions 720 overlap with the island portion 110 and the island portions 120 as viewed in the z direction. As a result, the heat generated from the semiconductor element 410 through the second portion 720 is processed as radiant heat by a radiation thermometer or the like, whereby the heat generation state of the semiconductor element 410 can be measured more accurately. Also, it is not necessary to ensure a space for providing an element such as a thermistor in the island portion 110 or the island portion 120. Accordingly, more accurate temperature measurement is possible while avoiding an increase in the size of the semiconductor device A1.

The second portions 720 of this embodiment overlap with the semiconductor elements 410 as viewed in the z direction. As a result, more of the heat generated from the semiconductor elements 410 can be detected through the second portions 720, and the temperature can be measured more accurately.

The second portions 720 overlap with the second electrodes 412 as viewed in the z direction and are in contact with the second electrodes 412. This makes it possible to further suppress the heat from the semiconductor elements 410 from being absorbed by the first portion 710. This corresponds to direct measurement of the temperature of the semiconductor elements 410 and is preferable for accurate temperature measurement.

As shown in FIG. 14, the method of forming the recesses 713 using the laser beam L can be used to remove a desired portion of the first portion 710 in a desired size, and is preferable for providing the second portions 720 at desired positions. Also, the second portions 720 are spaced apart from the wires 650. For this reason, it is possible to avoid unintentionally damaging the wires 650 when forming the recesses 713, for example.

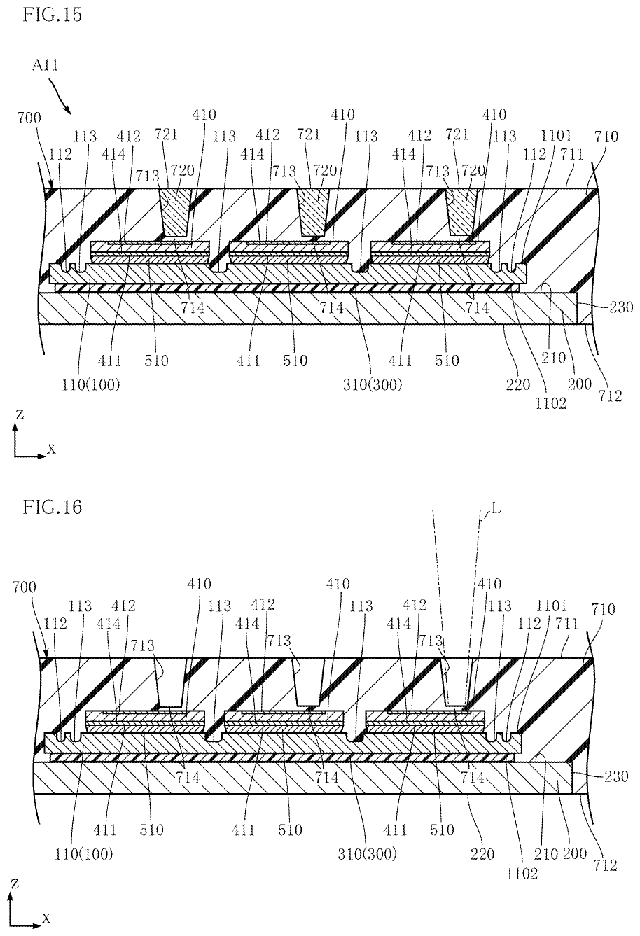

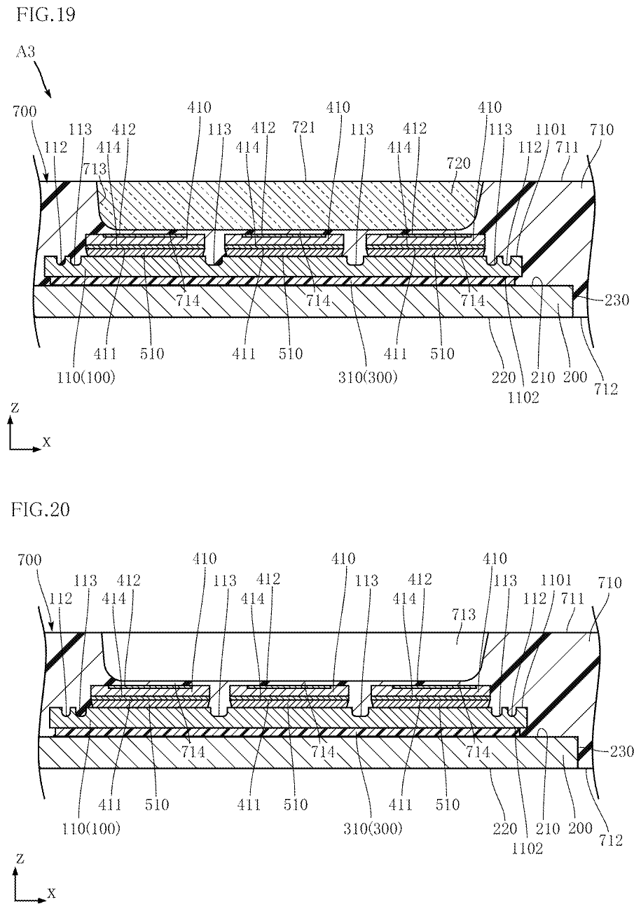

FIGS. 15 to 23 show modified examples and other embodiments of the present invention. Note that in these drawings, the same or similar elements as in the above embodiment are denoted by the same reference numerals as in the above embodiment.

FIG. 15 shows a first modified example of the semiconductor device A1. The semiconductor device A11 of this modified example differs from the semiconductor device A1 in the configuration of the first portion 710 and the second portion 720 of the sealing resin 700. In this embodiment, the first portion 710 has a plurality of interposed portions 714.

The interposed portions 714 are interposed between the second portions 720 and the semiconductor elements 410 in the z direction. In the illustrated example, the interposed portions 714 are in contact with the second portions 720 and the second electrodes 412 of the semiconductor elements 410. The dimension of the interposed portion 714 in the z direction is smaller than the dimension of the second portion 720 in the z direction.

FIG. 16 shows an example of a method for manufacturing the semiconductor device A11. Similarly to the example shown in FIG. 13, after the first portion 710 is formed by using a mold or the like, the laser beam L is emitted to the resin obverse surface 711 as shown in FIG. 16. When part of the first portion 710 is removed using the laser beam L, the part of the first portion 710 that covers the semiconductor elements 410 is left. This remaining portion becomes the interposed portion 714. Also, the recesses 713 formed by this processing are in the form of bottomed recesses that do not pass through the first portion 710. The second portions 720 shown in FIG. 15 are obtained by filling the recesses 713 with a resin material and curing the resin material.

According to this embodiment as well, more accurate temperature measurement is possible while avoiding an increase in the size of the semiconductor device A11. Also, although the interposed portion 714 is interposed between the second portion 720 and the semiconductor element 410, the heat generated from the semiconductor element 410 is transmitted to the interposed portion 714 and is radiated as radiant heat. Accordingly, the heat generation state of the semiconductor element 410 can be measured.

By making the z-direction dimension of the interposed portion 714 smaller than the z-direction dimension of the second portion 720, it is possible to prevent the interposed portion 714 from improperly insulating the heat from the semiconductor element 410. It should be noted that the z-direction dimension of the interposed portion 714 is preferably as thin as possible from the viewpoint of measurement accuracy, and for example, is preferably about 1/20 to ⅕ the z-direction dimension of the second portion 720, or about 10 μm to 100 μm. Also, in the step shown in FIG. 16, the semiconductor element 410 is preferably protected by preventing the laser light L from being emitted directly to the semiconductor element 410. In the following embodiments, unless otherwise specified, the interposed portion 714 may or may not be provided.

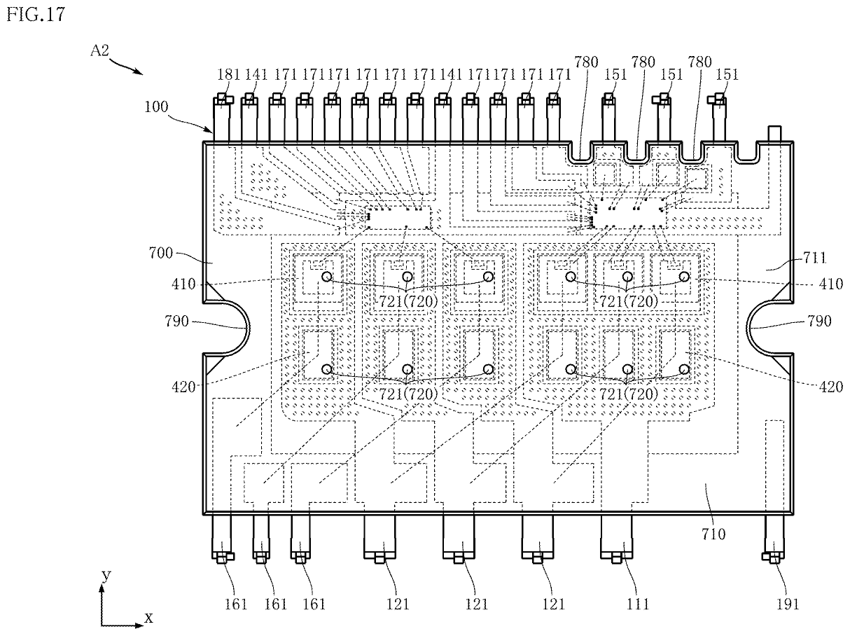

FIG. 17 shows a semiconductor device according to a second embodiment of the invention. The semiconductor device A2 of this embodiment has a different arrangement of the plurality of second portions 720 from the above-described first embodiment.

In the present embodiment, the plurality of second portions 720 include the second portions 720 that overlap with the semiconductor elements 410 and the second portions 720 that overlap with the semiconductor elements 420 as viewed in the z direction. The second portions 720 that overlap with the semiconductor elements 420 may be in contact with the upper surface electrodes 422, similarly to the second portions 720 of the semiconductor device A1, or the interposed portions 714 may be interposed between the upper surface electrodes 422 and the second portions 720 that overlap with the semiconductor elements 420.

According to this embodiment as well, more accurate temperature measurement is possible while avoiding an increase in the size of the semiconductor device A2. In addition to the temperature of the semiconductor element 410, it is possible to measure the temperature of the semiconductor elements 420, and thus the operating state of the semiconductor device A2 can be grasped more accurately.

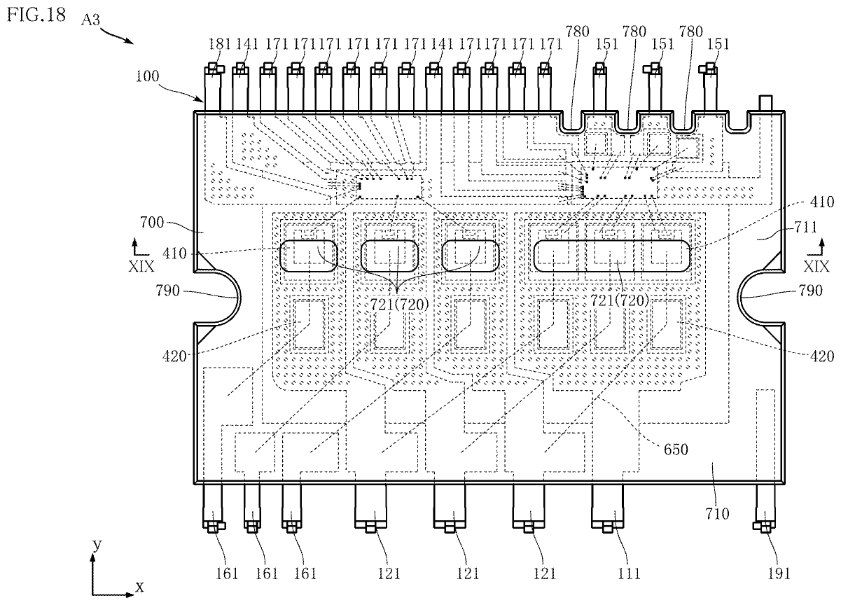

FIG. 18 shows a semiconductor device according to a third embodiment of the invention. The semiconductor device A3 of this embodiment differs from the embodiment described above in the configuration of the plurality of second portions 720.

In this embodiment, the second portion 720 that overlaps with the island portion 110 overlaps with the three semiconductor elements 410 as viewed in the z direction. Also, the second portion 720 overlaps with the wires 650 as viewed in the z direction.

FIG. 20 shows an example of a method for manufacturing the semiconductor device A3. In this manufacturing method, the recesses 713 of the first portion 710 are formed by etching. For example, etching is performed on a region that overlaps with the three semiconductor elements 410 mounted on the island portion 110 as viewed in the z direction to remove part of the first portion 710. Thereby, the recesses 713 are formed. Note that in the illustrated example, the interposed portions 714 covering the semiconductor elements 410 remain even after etching. Also, the wires 650 may be covered with the interposed portions 714 or may be accommodated in the recesses 713 while being exposed from the interposed portions 714. In this case, the second portions 720 are in contact with the wires 650.

According to this embodiment as well, more accurate temperature measurement is possible while avoiding an increase in the size of the semiconductor device A3. Also, by providing the second portion 720 having a size overlapping with the three semiconductor elements 410, the temperature measurement of the three semiconductor elements 410 can be performed more accurately.

In the method of forming the recesses 713 through etching, the influence on the wires 650 and the like can be suppressed by, for example, appropriately selecting the etchant.

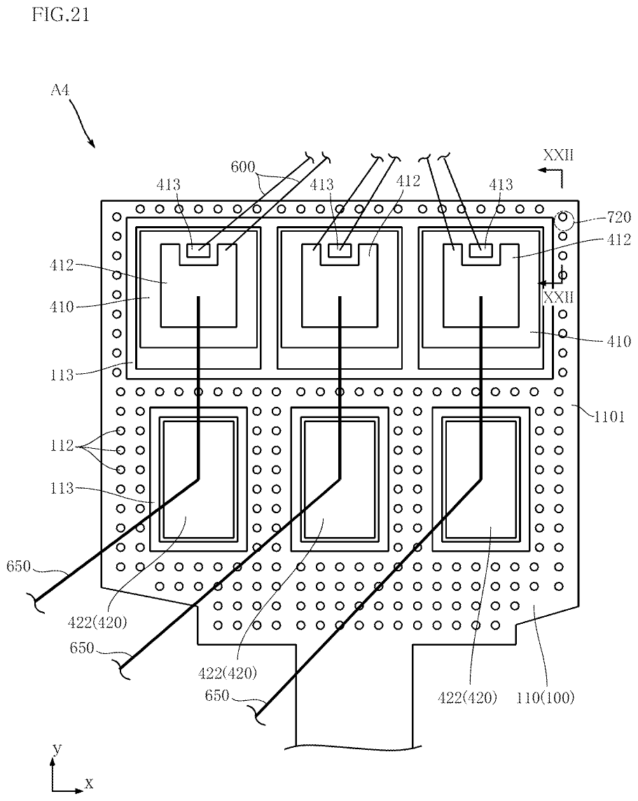

FIGS. 21 and 22 show a semiconductor device according to a fourth embodiment of the invention. The semiconductor device A4 of this embodiment has a different configuration of the plurality of second portions 720 from the embodiment described above.

In this embodiment, the second portion 720 overlaps with the island portion 110 but is spaced apart from the semiconductor element 410 as viewed in the z direction. The second portion 720 is in contact with the island portion 110. More specifically, the second portion 720 is in contact with the obverse surface 1101 of the island portion 110 and is further in contact with the recess 122. In other words, the recess 122 that overlaps with the second portion 720 as viewed in the z direction is partially filled with the second portion 720.

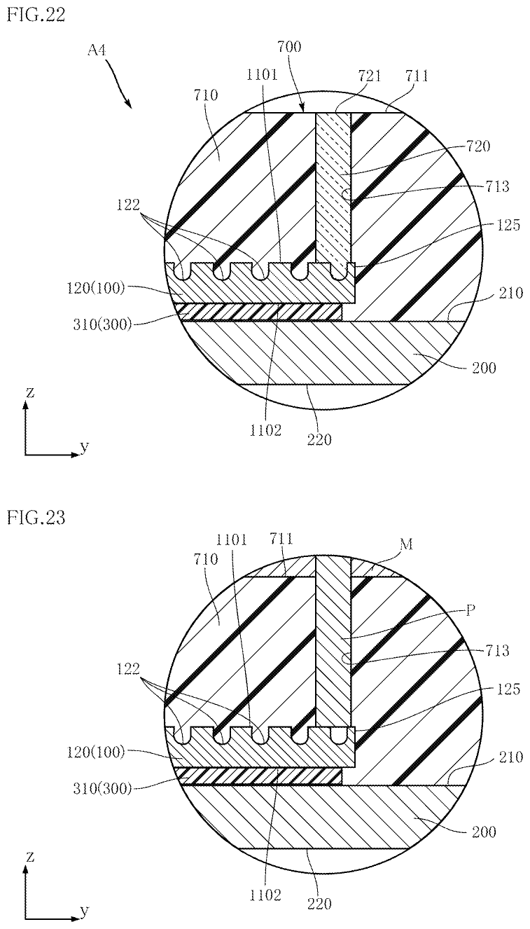

FIG. 23 shows an example of a method for manufacturing the semiconductor device A4. A pin P is used when a mold M is used to form the first portion 710. Before the resin material is injected into the cavity of the mold M, the pin P is brought into contact with part of the island portion 110 within the cavity. In the illustrated example, the tip surface of the pin P closes a recess 122. In this state, the resin material is injected and cured. As a result, a recess 713 shaped like the pin P is formed in the first portion 710. This recess 713 is in communication with the recess 122 closed by the pin P. Then, the recess 713 is filled with the resin material for forming the second portion 720. This resin material also fills the recess 122. The second portion 720 is formed by curing this resin material.

According to this embodiment as well, more accurate temperature measurement is possible while avoiding an increase in the size of the semiconductor device A4. As can be understood from the present embodiment, the second portion 720 is not limited to overlapping with the semiconductor element 410, and may also overlap with the island portion 110. Even with such a configuration, by utilizing the radiant heat from the island portion 110, more accurate temperature measurement can be performed. Also, the space for providing the second portion 720 can be made smaller than the space for mounting the thermistor on the island portion 110, for example, and thus the size of the semiconductor device A4 can be reduced.

The semiconductor device according to the present disclosure is not limited to the above-described embodiments. The specific configuration of each part of the semiconductor device according to the present disclosure can be modified in various ways.

Clause 1.

A semiconductor device, including:
a lead including an island portion having an obverse surface and a reverse surface that face mutually opposite sides in a thickness direction;
a semiconductor element mounted on the obverse surface of the island portion; and
a sealing resin covering the semiconductor element and the island portion, in which
the sealing resin includes a first portion and a second portion that overlaps with the island portion as viewed in the thickness direction and has a higher infrared transmittance than the first portion.

Clause 2.

The semiconductor device according to Clause 1, in which the second portion is exposed from the first portion.

Clause 3.

The semiconductor device according to Clause 1 or 2, in which the second portion is located on the obverse surface side with respect to the island portion in the thickness direction.

Clause 4.

The semiconductor device according to Clause 3, in which the second portion overlaps with the semiconductor element as viewed in the thickness direction.

Clause 5.

The semiconductor device according to Clause 4, in which the second portion is enclosed in the semiconductor element as viewed in the thickness direction.

Clause 6.

The semiconductor device according to Clause 4 or 5, in which the first portion includes an interposed portion that is interposed between the second portion and the semiconductor element.

Clause 7.

The semiconductor device according to Clause 6, in which a dimension in the thickness direction of the interposed portion is smaller than a dimension in the thickness direction of the second portion.

Clause 8.

The semiconductor device according to Clause 4 or 5, in which the second portion is in contact with the semiconductor element.

Clause 9.

The semiconductor device according to Clause 3, in which the second portion is spaced apart from the semiconductor element as viewed in the thickness direction.

Clause 10.

The semiconductor device according to Clause 9, in which the second portion is enclosed in the island portion as viewed in the thickness direction.

Clause 11.

The semiconductor device according to Clause 9 or 10, in which the second portion is in contact with the obverse surface of the island portion.

Clause 12.

The semiconductor device according to Clause 11, in which the island portion includes a plurality of recesses that are recessed in the thickness direction from the obverse surface, and the second portion is in contact with the recesses.

Clause 13.

The semiconductor device according to any one of Clauses 1 to 12, in which the semiconductor element is a switching element that includes a first electrode opposing the island portion, and a second electrode and a third electrode that are located on a side opposite to the first electrode in the thickness direction, the third electrode being a control electrode.

Clause 14.

The semiconductor device according to Clause 13 dependent on any one of Clauses 4 to 8, in which the second portion overlaps with the second electrode as viewed in the thickness direction.

Clause 15.

The semiconductor device according to any one of Clauses 1 to 14, further including a heat dissipation member that is fixed to the reverse surface of the island portion and is exposed from the sealing resin.

Clause 16.

The semiconductor device according to any one of Clauses 1 to 15, further including
a wire bonded to the semiconductor element,
in which the second portion is spaced apart from the wire. Clause 17.

The semiconductor device according to any one of Clauses 1 to 16, further including a control IC configured to control the semiconductor element.

### REFERENCE NUMERALS

A1, A2: Semiconductor device 100: Lead
110, 120, 130, 140, 150: Island portion
160, 170, 180: Pad portion
111, 121, 141, 151, 161, 171, 181, 191: Terminal portion
112, 122, 132, 142, 152, 182: Recess
113, 123: Trench 114, 124: Bent portion
115, 125: Corner portion 116, 126: Arc portion
1101, 1201: Obverse surface 1102, 1202: Reverse surface
200: Heat dissipation member 210: Bonding surface
220: Exposed surface
231: Smooth portion
230: Side surface
232: Rough portion
300: Bonding layer 310: Separate region
410, 420, 430, 440: Semiconductor element
411, 421: Bottom surface 412, 422, 432, 442: Upper surface
electrode
413, 423: Bottom surface electrode 490: Passive component
510, 520: Bonding material 600, 650: Wire
601: Wire 610: First bonding portion
605: Level difference portion 620: Second bonding portion
630: Reinforcement bonding portion 631: Disk portion
632: Cylinder portion 633: Pointed portion
690: Ring-shaped mark 700: Sealing resin
710: First portion 711: Resin obverse surface
712: Resin reverse surface 713: Recess
714: Interposed portion 720: Second portion
780, 790: Groove

1. A semiconductor device, comprising:
a lead including an island portion having an obverse surface and a reverse surface that face mutually opposite sides in a thickness direction;
a semiconductor element mounted on the obverse surface of the island portion; and
sealing resin covering the semiconductor element and the island portion,
wherein the sealing resin includes a first portion and a second portion that overlaps with the island portion as viewed in the thickness direction and has a higher infrared transmittance than the first portion.

2. The semiconductor device according to claim 1, wherein the second portion is exposed from the first portion.

3. The semiconductor device according to claim 1 or 2, wherein the second portion is located on the obverse surface side with respect to the island portion in the thickness direction.

4. The semiconductor device according to claim 3, wherein the second portion overlaps with the semiconductor element as viewed in the thickness direction.

5. The semiconductor device according to claim 4, wherein the second portion is enclosed in the semiconductor element as viewed in the thickness direction.

6. The semiconductor device according to claim 4 or 5, wherein the first portion includes an interposed portion that is interposed between the second portion and the semiconductor element.

7. The semiconductor device according to claim 6, wherein a dimension in the thickness direction of the interposed portion is smaller than a dimension in the thickness direction of the second portion.

8. The semiconductor device according to claim 4, wherein the second portion is in contact with the semiconductor element.

9. The semiconductor device according to claim 3, wherein the second portion is spaced apart from the semiconductor element as viewed in the thickness direction.

10. The semiconductor device according to claim 9, wherein the second portion is enclosed in the island portion as viewed in the thickness direction.

11. The semiconductor device according to claim 9, wherein the second portion is in contact with the obverse surface of the island portion.

12. The semiconductor device according to claim 11,
wherein the island portion includes a plurality of recesses that are recessed in the thickness direction from the obverse surface, and
the second portion is in contact with the recesses.

13. The semiconductor device according to claim 1, wherein the semiconductor element is a switching element that includes a first electrode opposing the island portion, and a second electrode and a third electrode that are located on a side opposite to the first electrode in the thickness direction, the third electrode being a control electrode.

14. The semiconductor device according to claim 13, wherein
the second portion is located on the obverse surface side with respect to the island portion in the thickness direction,
the second portion overlaps with the semiconductor element as viewed in the thickness direction, and
the second portion overlaps with the second electrode as viewed in the thickness direction.

15. The semiconductor device according to claim 1, further comprising a heat dissipation member that is fixed to the reverse surface of the island portion and is exposed from the sealing resin.

16. The semiconductor device according to claim 1, further comprising
a wire bonded to the semiconductor element,
wherein the second portion is spaced apart from the wire.

17. The semiconductor device according to claim 1, further comprising a control IC configured to control the semiconductor element.
